(19) United States
(12) Patent Application Publication
(10) Pub. No.: US 2021/0202899 A1
(43) Pub. Date: Jul. 1, 2021

(54) OLED DISPLAY SCREEN, DISPLAY PANEL AND MANUFACTURING METHOD THEREOF

(71) Applicants: BEIJING BOE DISPLAY TECHNOLOGY CO., LTD., Beijing (CN); BOE TECHNOLOGY GROUP CO., LTD., Beijing (CN)

(72) Inventors: Yonglian QI, Beijing (CN); Lianjie QU, Beijing (CN); Shan ZHANG, Beijing (CN); Hebin ZHAO, Beijing (CN); Xiaoling XU, Beijing (CN); Guangdong SHI, Beijing (CN); Zhiyong LIU, Beijing (CN)

(21) Appl. No.: 17/058,114

(22) PCT Filed: Apr. 20, 2020
(86) PCT No.: PCT/CN2020/085637

§ 371 Date: Nov. 23, 2020

(30) Foreign Application Priority Data
May 13, 2019 (CN) 201910394554.7

(51) Int. Cl. H01L 51/52; H01L 51/56; H01L 51/00

(52) U.S. Cl. CPC H01L 51/5253; H01L 51/56; H01L 51/005; H01L 27/3244; H01L 2251/5338; H01L 51/5221; H01L 2227/323

(57) ABSTRACT

An OLED display screen, a display panel and a manufacturing method thereof are disclosed in the present disclosure, the method includes: fabricating a TFT array substrate and an OLED component on a substrate, where the OLED component includes a first electrode, a light-emitting layer, and a second electrode; and fabricating a first organic layer on a side of the second electrode away from the substrate, where the first organic layer is capable of chemically reacting with the second electrode.

### CROSS-REFERENCE TO RELATED APPLICATION

The present application claims a priority to Chinese Patent Application No. 201910394554.7 filed in China May 13, 2019, the disclosure of which is incorporated herein in its entirety by reference.

### TECHNICAL FIELD

The present disclosure relates to the field of display technology, and in particular to an OLED display screen, a display panel and a manufacturing method thereof.

### BACKGROUND

At present, organic light-emitting diode (Organic Light-Emitting Diode, OLED) components are made of rigid substrates such as glass and metal, on which electrodes and each organic functional layer are fabricated. Such component is generally encapsulated by adding a cover plate, and a substrate and a cover plate are bonded with epoxy resin, so that a shield is formed between the substrate and the cover plate, separating the device from the air. Compositions such as water and oxygen in the air may penetrate into the inside of the device through only the epoxy resin between the substrate and the cover plate, thereby the function of encapsulation is achieved.

For the encapsulation of flexible OLED components, on one hand, a permeability of a package structure to vapor is required to be less than 5×10⁻⁶ g/m²d, and a permeability of the package structure to oxygen is less than 10⁻⁵c m2/m²d, on the other hand, the packaging structure is required to meet a characteristic of flexibility, therefore, most of them currently use thin film encapsulation.

Nonetheless, the thin film encapsulation has a low water resistance and low oxygen resistance, and an interlayer separation and cracking may occur between inorganic layers and organic layers after many bends, which affects a service life of the component.

### SUMMARY

A method of manufacturing an OLED display panel is provided in the present disclosure, including:

fabricating a TFT array substrate and an OLED component on a substrate, where the OLED component includes a first electrode, a light-emitting layer, and a second electrode; and

fabricating a first organic layer on a side of the second electrode away from the substrate, where the first organic layer is capable of chemically reacting with the second electrode.

A material for fabricating the first organic layer includes: alkyl mercaptan.

The second electrode is an Ag electrode.

The first organic layer is capable of chemically reacting with the second electrode, further including:

without external force, spontaneously bonding sulfur in the alkyl mercaptan and Ag atoms in the Ag electrode by coordinate bond.

The method further includes:

forming a first inorganic silicon layer on the first organic layer;

depositing a second organic layer on the first inorganic silicon layer; and

forming a second inorganic silicon layer on the second organic layer.

The first inorganic silicon layer includes a silicon oxide layer or a silicon nitride layer; and

the second inorganic silicon layer includes a silicon oxide layer or a silicon nitride layer.

The alkyl mercaptan includes: cetyl mercaptan and/or octadecyl mercaptan.

An OLED display panel is further provided in the present disclosure, including: a substrate, a TFT array substrate and an OLED component, where the OLED component includes: a first electrode, a light-emitting layer, and a second electrode; and the OLED display panel further includes:

a first organic layer formed on a side of the second electrode, where the first organic layer is capable of chemically reacting with the second electrode.

A material for fabricating the first organic layer includes: an alkyl mercaptan.

The second electrode is an Ag electrode.

The first inorganic silicon layer is a silicon oxide layer or a silicon nitride layer.

The display panel further includes:

a first inorganic silicon layer formed on the first organic layer;

a second organic layer deposited on the first inorganic silicon layer; and

a second inorganic silicon layer formed on the second organic layer.

The first inorganic silicon layer includes a silicon oxide layer or a silicon nitride layer.

The second inorganic silicon layer includes a silicon oxide layer or a silicon nitride layer.

The alkyl mercaptan includes: cetyl mercaptan and/or octadecyl mercaptan.

An OLED display screen is further provided in the present disclosure, including the above-mentioned display panel.

A display apparatus is further provided in the present disclosure, including: a signal controller, a display driver, and an OLED display screen; where the OLED display screen includes the above-mentioned display panel.

### BRIEF DESCRIPTION OF THE DRAWINGS

FIG. 1 is a schematic diagram of an encapsulation structure of an OLED component in the related art;

FIG. 2 is a flowchart of a method of manufacturing an OLED display panel according to embodiments of the present disclosure;

FIG. 3A to FIG. 3C are structural schematic diagrams of a method of manufacturing an OLED display panel according to embodiments of the present disclosure at each manufacturing stage;

FIG. 4 is a structural schematic diagram of an OLED display panel according to embodiments of the present disclosure.

### DETAILED DESCRIPTION

To describe the objective, the technical solutions and the advantages of embodiments of the present disclosure more clearly, the technical solutions in embodiments of the present disclosure are described clearly and completely in conjunction with drawings in the embodiments of the present disclosure.

The embodiments of the present disclosure are described in detail below. Examples of the embodiments are shown in the drawings, same or similar reference numerals represent same or similar elements or elements with same or similar functions. The following embodiments described with reference to the drawings are exemplary and intended to explain the present disclosure, and should not be regarded as limiting the present disclosure.

Those skilled in the art will understand that, unless specifically stated, singular forms “a”, “an”, “said” and “the” used herein may also comprise plural forms. The term “and/or” used herein comprises all or any unit and all combinations of one or more associated listed items.

It should be noted that all expressions “first” and “second” in embodiments of the present disclosure are used to distinguish two different entities with the same name or two different parameters. It can be seen that “first” and “second” are only for convenience of expression, and should not be construed as limiting the embodiments of the present disclosure. This will not be described in subsequent embodiments.

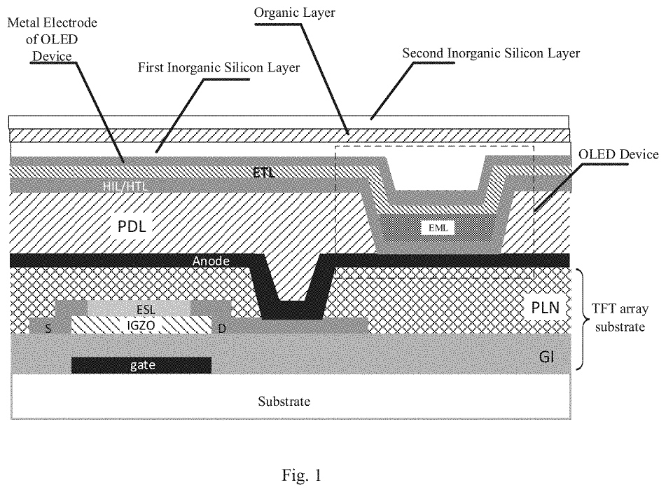

A thin film encapsulation structure is shown in FIG. 1, which is composed of an organic material and an inorganic layer material physically alternately, including a first inorganic layer made of silicon nitride or silicon oxide, an organic layer as a flat layer, and a second inorganic layer made of silicon nitride or silicon oxide. Silicon oxide or silicon nitride, which is an inorganic insulating material, has a high water resistance and oxygen resistance, however, a membrane surface of an inorganic insulating layer itself is rough and has pinholes, which is easy to cause external water and oxygen to invade, and provide a way for water and oxygen to invade the interior, reducing the ability of blocking water and oxygen of the inorganic insulating layer and that of the encapsulation structure formed by the inorganic insulating layer. In addition, interlayer separation and cracking may occur between an inorganic layer and an organic layer after many bends, so that a flexible display device is directly subjected to destructive damage, affecting the service life of the device.

In the technical solutions of the present disclosure, when a display panel is encapsulated, an alkyl mercaptan is used to self-assemble a first organic layer on a metal electrode surface of an OLED component, and then a first inorganic silicon layer is formed on the first organic layer. In a self-assembly process of alkyl mercaptan, a sulfur bond in alkyl mercaptan is strongly bonded to a metal ion in the metal electrode. Because the sulfur bond in alkyl mercaptan and a surface of the metal electrode are bonded by strong chemical bonding, it can effectively prevent water and oxygen, and the metal electrode of the OLED component has a chemical bond with the alkyl mercaptan, which is easier to achieve flexible structure, and it is not easy to crack and separate after many bends, which can improve the reliability of the device, and prolong lifetime.

Furthermore, alkyl in the first organic layer and silicon in the first inorganic silicon layer are also chemically bonded, which is very strong and has no gaps, effectively preventing water and oxygen. Since chemical bonds are formed between the first inorganic silicon layer and the alkyl mercaptan, it is easier to realize a flexible structure, and it is not easy to crack and separate after many bends, thereby improving the reliability of the device and prolonging lifetime.

The technical solution of the present disclosure will be described in detail below in conjunction with drawings.

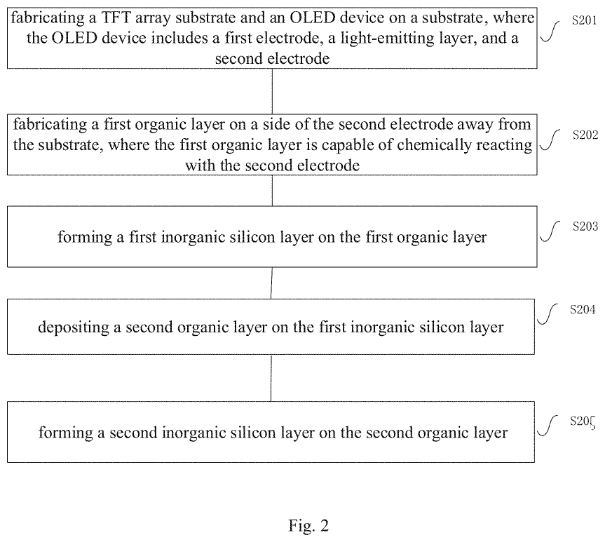

A method of manufacturing an OLED display panel is provided according to embodiments of the present disclosure, and specific processes are shown in FIG. 2, including following steps:

step S201: fabricating a TFT array substrate and an OLED component on a substrate, where the OLED component includes a first electrode, a light-emitting layer, and a second electrode.

The TFT array substrate includes: a gate insulating layer (GI) and a planarization layer (PLN). In the gate insulating layer (GI) and the planarization layer (PLN), there is a field effect transistor formed by an indium gallium zinc oxide (Indium Gallium Zinc Oxide, IGZO) and an etch stop layer (Etch Stop Layer, ESL), including a source (S), a drain (D) and a gate (gate). On the PLN layer of the TFT array substrate, an anode of the OLED component is formed. A pixel definition layer (PDL) is formed on the anode, and a hole injection layer/hole transport layer (HIL/HTL), a light emitting layer (EML), and an electron transport layer (ETL) are formed on the pixel definition layer.

Step S202: fabricating a first organic layer on a side of the second electrode away from the substrate, where the first organic layer is capable of chemically reacting with the second electrode.

A material for fabricating the first organic layer includes: an alkyl mercaptan. The second electrode is an Ag electrode.

The first organic layer is capable of chemically reacting with the second electrode, further comprising:

without external force, spontaneously bonding sulfur in the alkyl mercaptan and Ag atoms in the Ag electrode by coordinate bond.

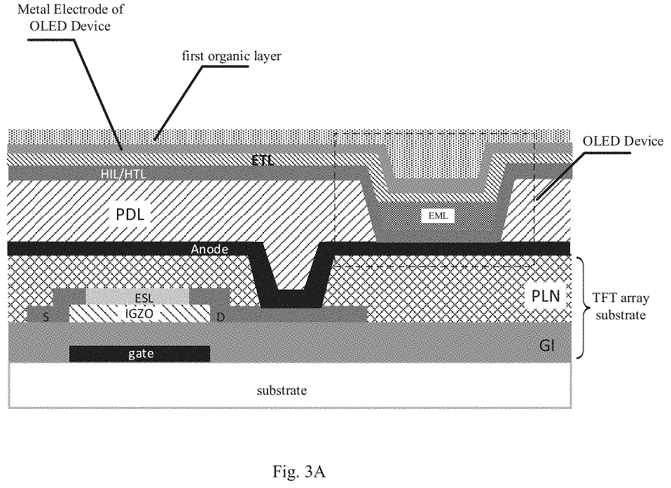

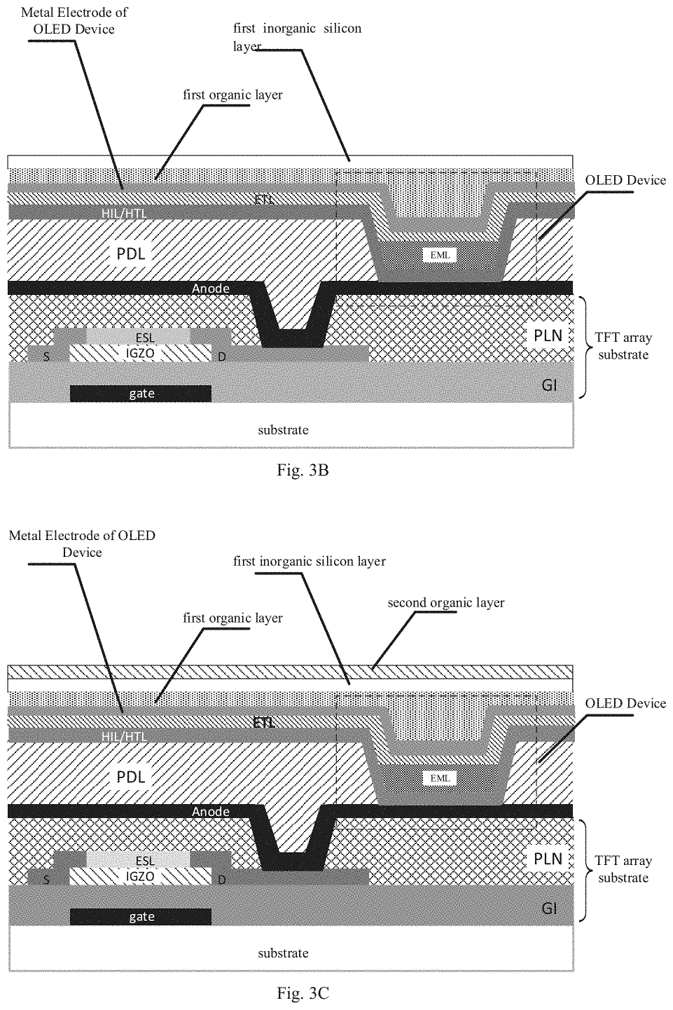

In this step, alkyl mercaptan is used to self-assemble on the surface of the metal electrode of the OLED component, where self-assembly refers to a process in which molecules with appropriate structures (such as amphiphilic molecules) spontaneously form, through intermolecular chemical bonds or weak interactions without external force, a stable ordered three-dimensional structure with a lowest free energy. That is to say, when the alkyl mercaptan is used for self-assembly on the surface of the metal electrode of the OLED component in the step, the sulfur in the alkyl mercaptan and the metal atom in the metal electrode bond spontaneously through the coordination bond without external force, thereby forming the first organic layer having a stable ordered three-dimensional structure and strong bonding with the surface of the metal electrode, as shown in FIG. 3a.

The alkyl mercaptan includes: cetyl mercaptan or octadecyl,

or the alkyl mercaptan includes: cetyl mercaptan and octadecyl mercaptan.

Because the sulfur in alkyl mercaptan and metal in a surface of the metal electrode are bonded by chemical bonds, it is very strong, so it can effectively prevent water and oxygen, and the metal electrode of the OLED component has a chemical bond with the alkyl mercaptan, which is easier to achieve a flexible structure, and it is not easy to crack and separate after many bends, which can improve the reliability of the device, and prolong lifetime.

Step S203: forming a first inorganic silicon layer on the first organic layer;

Specifically, a chemical vapor deposition method is adopted to deposit silicon nitride or silicon oxide on the first organic layer to form the first inorganic silicon layer; that is, the first inorganic silicon layer deposited on the first organic layer may be silicon nitride layer or silicon oxide layer, as shown in FIG. 3b.

Alkyl in the first organic layer and silicon in the first inorganic silicon layer are chemically bonded, which is very strong and has no gaps, effectively preventing water and oxygen. Since chemical bonds are formed between the first inorganic silicon layer and the alkyl mercaptan, it is easier to realize a flexible structure, and it is not easy to crack and separate after many bends, thereby improving the reliability of the device and prolonging lifetime.

Further, in order to enhance the display panel stronger, the following encapsulation steps may be included:

step S204: depositing a second organic layer on the first inorganic silicon layer.

In this step, inkjet printing may be performed on the first inorganic silicon layer to deposit the second organic layer, as shown in FIG. 3c; a material of the second organic layer may mainly be epoxy resin organic materials.

Step S205: forming a second inorganic silicon layer on the second organic layer.

In this step, a chemical vapor deposition method is adopted to deposit silicon nitride or silicon oxide on the second organic layer to form the second inorganic silicon layer; that is, the second inorganic silicon layer deposited on the second organic layer may be silicon nitride layer or silicon oxide layer, thereby completing the encapsulation process of the OLED display panel.

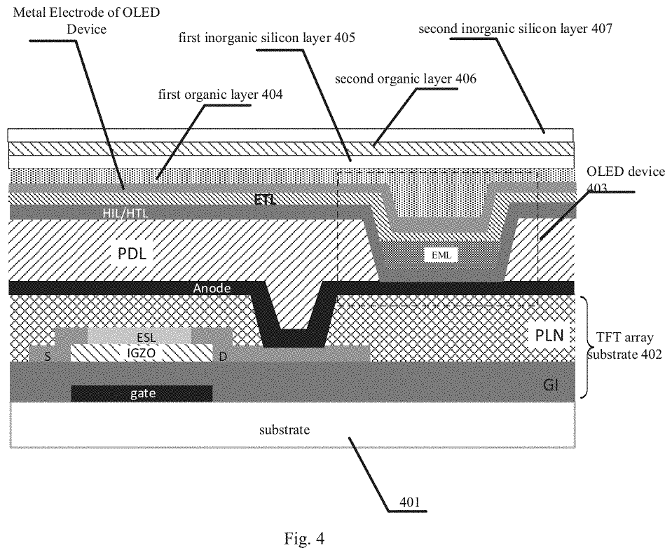

Based on the above-mentioned method of manufacturing an OLED display panel, a structure of an OLED display panel provided by an embodiment of the present disclosure is shown in FIG. 4, including: a substrate 401, a TFT array substrate 402 on the substrate 401, and an OLED component formed on the TFT array substrate, where the OLED component includes a first electrode, a light-emitting layer, and a second electrode; on a side of the second electrode of the OLED component 403 away from the substrate, a first organic layer 404 is formed by self-assembly using alkyl mercaptan, and a first inorganic silicon layer 405 is deposited on the first organic layer 404.

sulfur bonds in the first organic layer 404 formed on the basis of alkyl mercaptan is strongly boned with metal ions in the metal electrode of the OLED component 403. Because the sulfur bonds in alkyl mercaptan and metal in a surface of the metal electrode are bonded by chemical bonds, it is very strong, so it can effectively prevent water and oxygen, and the metal electrode of the OLED component has a chemical bond with the alkyl mercaptan, which is easier to achieve a flexible structure, and it is not easy to crack and separate after many bends, which can improve the reliability of the device, and prolong lifetime.

Further, the second electrode of the OLED component 403 may specifically be an Ag electrode.

The alkyl mercaptan includes: cetyl mercaptan or octadecyl,

or the alkyl mercaptan includes: cetyl mercaptan and/or octadecyl mercaptan.

The first inorganic silicon layer 405 may be a silicon nitride layer or a silicon oxide layer. Silicon in the first inorganic silicon layer 405 and Alkyl formed on basis of alkyl mercaptan in the first organic layer 404 are also chemically bonded, which is very strong and has no gaps, effectively preventing water and oxygen. Since chemical bonds are formed between the first inorganic silicon layer and the alkyl mercaptan, it is easier to realize a flexible structure, and it is not easy to crack and separate after many bends, thereby improving the reliability of the device and prolonging lifetime.

Further, an OLED display panel provided by an embodiment of the present disclosure may further include: a second organic layer 406 deposited on the first inorganic silicon layer 405, and a second inorganic silicon layer 407 deposited on the second organic layer 406.

The second inorganic silicon layer includes a silicon oxide layer or a silicon nitride layer.

Embodiments of the present disclosure also provide an OLED display screen, including the above-mentioned OLED display panel.

In the technical solutions of the present disclosure, when a display panel is encapsulated, an alkyl mercaptan is used to self-assemble a first organic layer on a metal electrode surface of an OLED component, and then a first inorganic silicon layer is formed on the first organic layer. The sulfur in the alkyl mercaptan and the metal atom in the metal electrode bond spontaneously through the coordination bond without external force, thereby forming the first organic layer having a stable ordered three-dimensional structure and strong bonding with the surface of the metal electrode, so it can effectively prevent water and oxygen, and the metal electrode of the OLED component has a chemical bond with the alkyl mercaptan, which is easier to achieve a flexible structure, and it is not easy to crack and separate after many bends, which can improve the reliability of the device, and prolong lifetime.

Furthermore, alkyl in the first organic layer and silicon in the first inorganic silicon layer are also chemically bonded, which is very strong and has no gaps, effectively preventing water and oxygen. Since chemical bonds are formed between the first inorganic silicon layer and the alkyl mercaptan, it is easier to realize a flexible structure, and it is not easy to crack and separate after many bends, thereby improving the reliability of the device and prolonging lifetime.

Embodiments of the present disclosure also provide a display apparatus, including: a signal controller, a display driver, and an OLED display screen; where the OLED display screen includes the above-mentioned display panel.

Those skilled in the art can understand that the various operations, methods, steps in the process, measures, and solutions having been discussed in this disclosure can be alternated, changed, combined, or deleted. Further, the various operations, methods, other steps in the process, measures, and solutions that have been discussed in the present disclosure can also be alternated, changed, rearranged, decomposed, combined, or deleted. Further, the various operations, methods, other steps in the process, measures, and solutions that are disclosed in the present disclosure can also be alternated, changed, rearranged, decomposed, combined, or deleted.

Those of ordinary skill in the art should understand: the discussion of any of the above embodiments is only exemplary, and is not intended to imply that the scope of the present disclosure (including the claims) is limited to these examples. Under the idea of the present disclosure, the technical features of the above embodiments or different embodiments can also be combined, the steps can be implemented in any order, and there are many other changes in different aspects of the present disclosure as described above, which are not provided in details for the sake of brevity. Therefore, any omissions, modifications, equivalent replacements, improvements, etc. made within the spirit and principles of the present disclosure should be included in the protection scope of the present disclosure.

1. A method of manufacturing an OLED display panel, comprising:
fabricating a TFT array substrate and an OLED component on a substrate, wherein the OLED component comprises a first electrode, a light-emitting layer, and a second electrode; and
fabricating a first organic layer on a side of the second electrode away from the substrate, wherein the first organic layer is capable of chemically reacting with the second electrode.

2. The method according to claim 1, wherein a material for fabricating the first organic layer comprises: alkyl mercaptan.

3. The method according to claim 1, wherein the second electrode is an Ag electrode.

4. The method according to claim 2, wherein the first organic layer being capable of chemically reacting with the second electrode, further comprising:
without external force, spontaneously bonding sulfur in the alkyl mercaptan and Ag atoms in an Ag electrode by coordinate bond.

5. The method according to claim 1, further comprising:
forming a first inorganic silicon layer on the first organic layer;
depositing a second organic layer on the first inorganic silicon layer; and
forming a second inorganic silicon layer on the second organic layer.

6. The method according to claim 5, wherein the first inorganic silicon layer comprises: a silicon oxide layer or a silicon nitride layer; and
the second inorganic silicon layer comprises a silicon oxide layer or a silicon nitride layer.

7. The method according to claim 2, wherein the alkyl mercaptan comprises: cetyl mercaptan and/or octadecyl mercaptan.

8. An OLED display panel, comprising: a substrate, a TFT array substrate and an OLED component, wherein the OLED component comprises a first electrode, a light-emitting layer, and a second electrode; and the OLED display panel further comprises:
a first organic layer formed on a side of the second electrode, wherein the first organic layer is capable of chemically reacting with the second electrode.

9. The display panel according to claim 8, wherein a material for fabricating the first organic layer comprises: an alkyl mercaptan.

10. The display panel according to claim 8, wherein the second electrode is an Ag electrode.

11. The display panel according to claim 8, further comprising:
a first inorganic silicon layer formed on the first organic layer;
a second organic layer deposited on the first inorganic silicon layer; and
a second inorganic silicon layer formed on the second organic layer.

12. The display panel according to claim 11, wherein the first inorganic silicon layer comprises: a silicon oxide layer or a silicon nitride layer; and
the second inorganic silicon layer comprises a silicon oxide layer or a silicon nitride layer.

13. The display panel according to claim 9, wherein the alkyl mercaptan comprises: cetyl mercaptan and/or octadecyl mercaptan.

14. An OLED display screen, comprising the OLED display panel according to claim 8.

15. A display apparatus, comprising: a signal controller, a display driver, and an OLED display screen; wherein the OLED display screen comprises the display panel according to claim 8.

16. The method according to claim 3, wherein the first organic layer being capable of chemically reacting with the second electrode, further comprising:
without external force, spontaneously bonding sulfur in the alkyl mercaptan and Ag atoms in the Ag electrode by coordinate bond.
